(19) United States
(12) Patent Application Publication
(10) Pub. No.: US 2015/0371861 A1
(43) Pub. Date: Dec. 24, 2015

(54) PROTECTIVE SILICON OXIDE PATTERNING

(71) Applicant: APPLIED MATERIALS, INC., Santa Clara, CA (US)

(72) Inventors: Zihui LI, Santa Clara, CA (US); Zhijun CHEN, San Jose, CA (US); Anchuan WANG, San Jose, CA (US)

(21) Appl. No.: 14/312,202

(22) Filed: Jun. 23, 2014

(51) Int. Cl. H01L 21/308; H01L 21/3065

(52) U.S. Cl. CPC H01L 21/3086; H01L 21/3065

(57) ABSTRACT

A method of patterning a substrate is described and include two possible layers which may be easily integrated into a photoresist patterning process flow and avoid an observed photoresist peeling problems. A conformal carbon layer or a conformal silicon-carbon-nitrogen layer may be formed between an underlying silicon oxide layer and an overlying photoresist layer. Either inserted layer may avoid remotely-excited fluorine etchants from diffusing through the photoresist and chemically degrading the silicon oxide. The conformal carbon layer may be removed at the same time as the photoresist and the conformal silicon-carbon-nitrogen layer may be removed at the same time as the silicon oxide, limiting process complexity.

### FIELD

Embodiments of the invention relate to patterning a substrate.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which removes one material faster than another helping e.g. a pattern transfer process proceed. Such an etch process is said to be selective of the first material relative to the second material. As a result of the diversity of materials, circuits and processes, etch processes have been developed with a selectivity towards a variety of materials.

Dry etch processes are often desirable for selectively removing material from semiconductor substrates. The desirability stems from the ability to gently remove material from miniature structures with minimal physical disturbance. Dry etch processes also allow the etch rate to be more abruptly stopped by removing the gas phase reagents. Some dry-etch processes involve the exposure of a substrate to remote plasma by-products formed from one or more precursors. For example, remote plasma excitation of ammonia and nitrogen trifluoride enables silicon oxide to be selectively removed from a patterned substrate when the plasma effluents are flowed into the substrate processing region. Dry etch process sequences are needed to selectively remove silicon oxide while improving material compatibility.

### SUMMARY

A method of patterning a substrate is described and include two possible layers which may be easily integrated into a photoresist patterning process flow and avoid an observed photoresist peeling problems. A conformal carbon layer or a conformal silicon-carbon-nitrogen layer may be formed between an underlying silicon oxide layer and an overlying photoresist layer. Either inserted layer may avoid remotely-excited fluorine etchants from diffusing through the photoresist and chemically degrading the silicon oxide. The conformal carbon layer may be removed at the same time as the photoresist and the conformal silicon-carbon-nitrogen layer may be removed at the same time as the silicon oxide, limiting process complexity.

Embodiments of the invention include methods of patterning a substrate. The methods include forming a silicon oxide layer on the substrate. The methods further include forming a conformal carbon layer on the silicon oxide. The methods further include forming a photoresist layer on the conformal carbon layer. The methods further include patterning the photoresist layer with a pattern to form a patterned photoresist layer. The operation of patterning the photoresist layer also patterns the conformal carbon layer with the pattern to form a patterned conformal carbon layer. The methods further include etching the pattern into the silicon oxide layer using both the patterned photoresist layer and the patterned conformal carbon layer as the mask. Etching the pattern into the silicon oxide layer includes forming a patterned silicon oxide layer from the silicon oxide layer. The methods further include removing the patterned photoresist layer and the patterned carbon layer in a single operation. The methods further include patterning the substrate using the patterned silicon oxide layer. The methods further include removing the patterned silicon oxide layer.

Embodiments of the invention include methods of patterning a substrate. The methods include forming a silicon oxide layer on the substrate. The methods further include forming a conformal silicon-containing layer on the silicon oxide. The conformal silicon-containing layer further includes carbon. The methods further include forming a photoresist layer on the conformal silicon-containing layer. The methods further include patterning the photoresist layer with a pattern to form a patterned photoresist layer. The methods further include etching the pattern into the conformal silicon oxide layer. Etching the pattern into the conformal silicon oxide layer includes forming a patterned silicon oxide layer from the silicon oxide layer. The operation of etching the pattern into the silicon oxide layer also patterns the conformal silicon-containing layer with the pattern to form a patterned conformal silicon-containing layer. The methods further include removing the patterned photoresist layer. The methods further include removing the patterned photoresist layer also transforms the silicon-containing layer into a patterned silicon oxide capping layer. The methods further include patterning the substrate using the patterned silicon oxide capping layer and the patterned silicon oxide layer. The methods further include removing the patterned silicon oxide capping layer and the patterned silicon oxide layer in a single operation.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### DESCRIPTION OF THE DRAWINGS

A further understanding of the nature and advantages of the disclosed technology may be realized by reference to the remaining portions of the specification and the drawings.

FIG. 1 shows a method of patterning a substrate according to the prior art.

FIGS. 2A, 2B and 2C show cross-sectional views during patterning a substrate according to the prior art.

FIG. 3 shows a method of patterning a substrate according to embodiments of the invention.

FIGS. 4A, 4B, 4C, 4D, 4E and 4F show cross-sectional views during patterning a substrate according to embodiments of the invention.

FIG. 5 shows a method of patterning a substrate according to embodiments of the invention.

FIGS. 6A, 6B, 6C, 6D, 6E and 6F show cross-sectional views during patterning a substrate according to embodiments of the invention.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

A method of patterning a substrate is described and include two possible layers which may be easily integrated into a photoresist patterning process flow and avoid an observed photoresist peeling problems. A conformal carbon layer or a conformal silicon-carbon-nitrogen layer may be formed between an underlying silicon oxide layer and an overlying photoresist layer. Either inserted layer may avoid remotely-excited fluorine etchants from diffusing through the photoresist and chemically degrading the silicon oxide. The conformal carbon layer may be removed at the same time as the photoresist and the conformal silicon-carbon-nitrogen layer may be removed at the same time as the silicon oxide, limiting process complexity regardless of which option is selected.

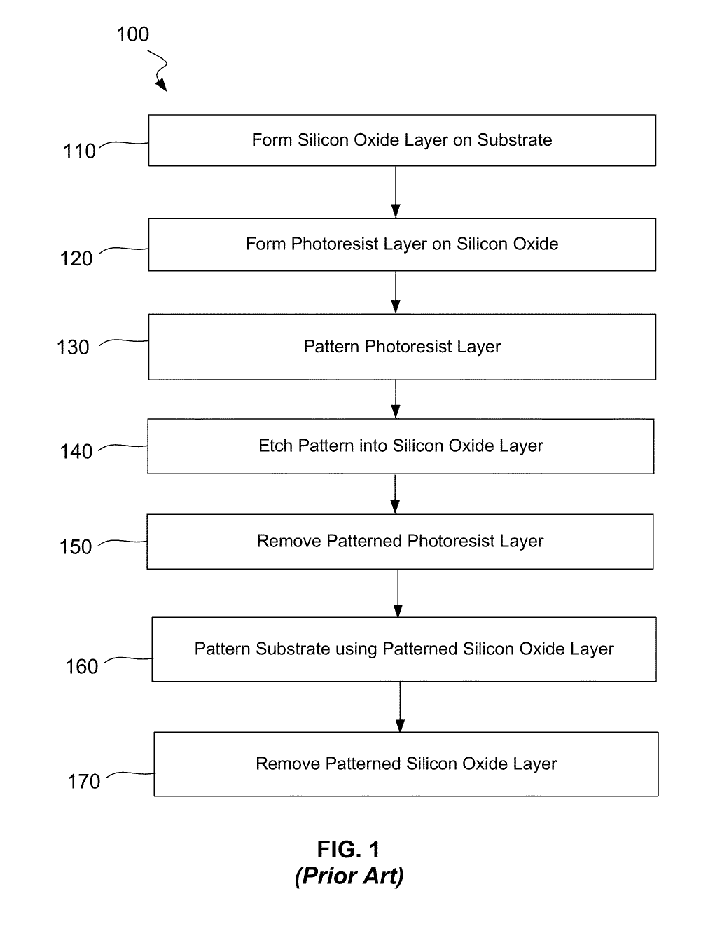

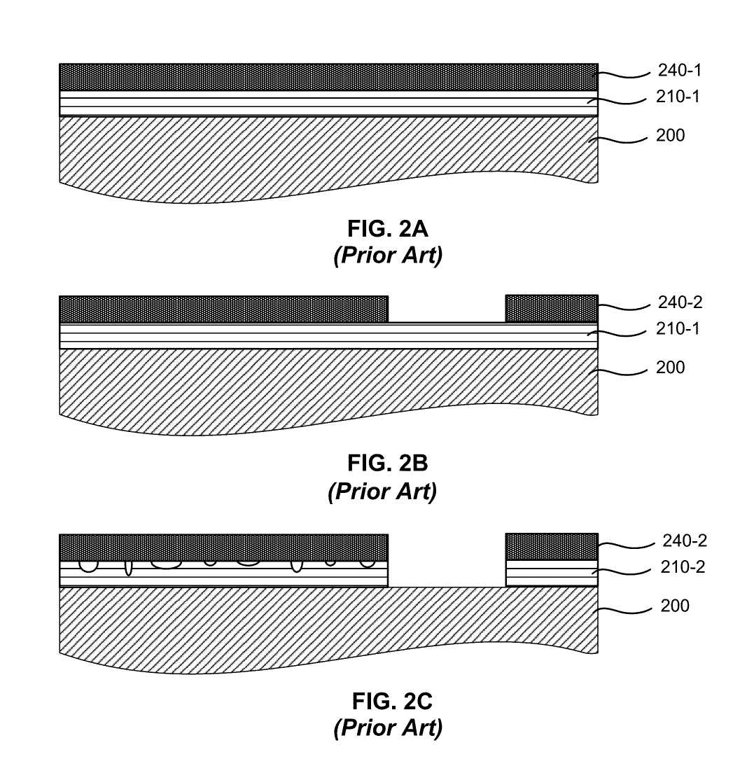

Context for the present invention is provided with reference to FIG. 1 which shows a method of patterning a substrate 100 according to the prior art. Reference will concurrently be made to FIGS. 2A-2C which are cross-sectional views at various points during the method of FIG. 1. A silicon oxide layer 210-1 is formed on a substrate 200 in operation 110. A photoresist layer 240-1 is then formed on substrate 200 in operation 120. Photoresist layer 240-1 is patterned (operation 130) and the patterned photoresist layer 240-2 is used as a mask to etch the pattern into silicon oxide layer 210-1 to form patterned silicon oxide layer 210-2 in operation 140. Some especially delicate etch processes to be discussed shortly have been found to penetrate through patterned photoresist layer 240-2 and negatively impact the integrity of patterned silicon oxide layer 210-2. The existence of this problem has not be appreciated prior to the present work. Patterned photoresist layer 240-2 may peel off due to the lack of integrity. No further cross-sectional views are shown as a result of the potential defect. For illustration purposes, however, the remainder of the intended operations will be summarized. In operation 150, patterned photoresist layer 240-2 would be removed. The substrate would be patterned (operation 160) using patterned silicon oxide layer 210-2 as a mask. The patterning may be an etch process or an ion implantation process in this example or in the other examples described herein. After patterning, patterned silicon oxide layer 210-2 would be removed in operation 170.

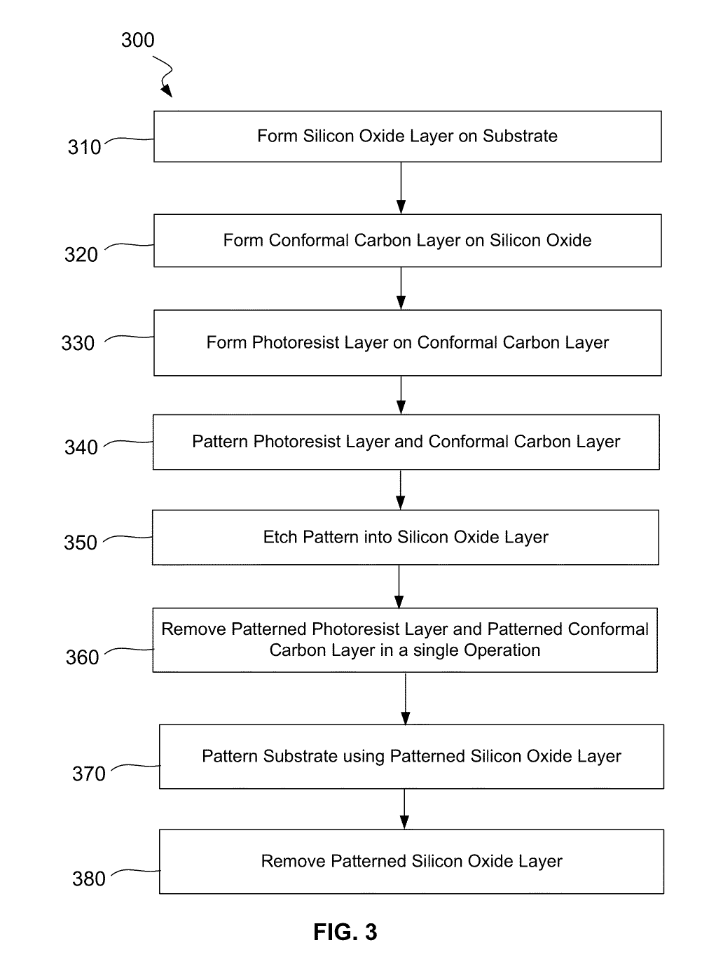

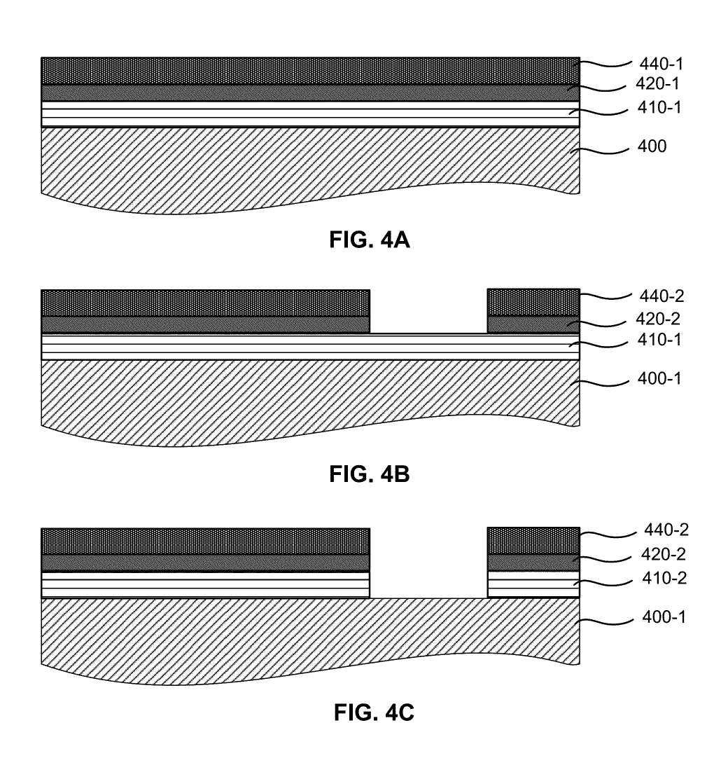

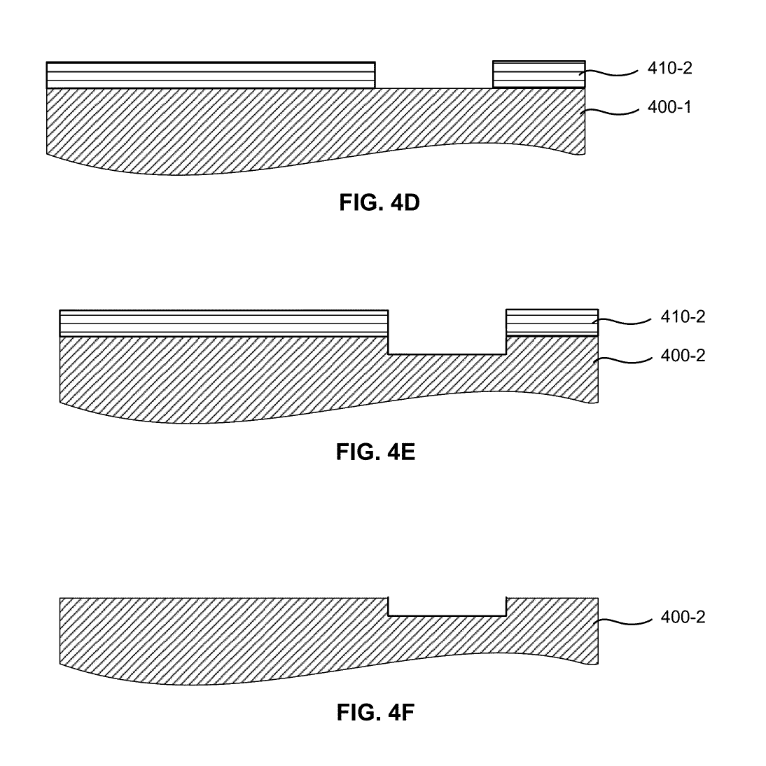

In light of this context, reference is now made to FIG. 3 which shows a method of patterning a substrate 400-1 according to embodiments of the invention. Reference will concurrently be made to FIGS. 4A-4F which are cross-sectional views at various points during the method of FIG. 3. A silicon oxide layer 410-1 is formed on a substrate 400-1 in operation 310. A conformal carbon layer 420-1 is formed on silicon oxide layer 410-1 in operation 320. A photoresist layer 440-1 is then formed on conformal carbon layer 420-1 in operation 330. Photoresist layer 440-1 and conformal carbon layer 420-1 are patterned (operation 340) in the same operation, in embodiments, to simplify the processing sequence. Following patterning in operation 340, photoresist layer 440-1 is transformed into patterned photoresist layer 440-2 and conformal carbon layer 420-1 is transformed into patterned conformal carbon layer 420-2. Single operation patterning is enabled by the selected material similarity of conformal carbon layer 420-1 to photoresist layer 440-1. However, conformal carbon layer 420-1 does not allow the penetration of etchants whereas photoresist layer 440-1 may be porous to etchants, according to embodiments. Suitable materials for conformal carbon layer 420-1 will be described following completion of the discussion of the operations of method 300.

Patterned photoresist layer 440-2 and patterned conformal carbon layer 420-2 are used in tandem as a mask to etch the pattern into silicon oxide layer 410-1 to form patterned silicon oxide layer 410-2 in operation 350. Patterned conformal carbon layer 420-2 of various forms described herein have shown ability to stop diffusion of delicate etch process etchants and protect the integrity of patterned silicon oxide layer 410-2 in embodiments. Patterned photoresist layer 440-2 may remain attached to the stack of materials rather than peeling off as a result of the presence of patterned conformal carbon layer 420-2. In operation 360, patterned photoresist layer 440-2 and patterned conformal carbon layer 420-2 are removed. Operation 360 may involve exposing the patterned substrate to an oxygen atmosphere to remove patterned photoresist layer 440-2 and patterned conformal carbon layer 420-2. The substrate is patterned (operation 370) using patterned silicon oxide layer 410-2 as a mask. The patterning may again be an etch process, as shown, or an ion implantation process. In the example, substrate 400-1 is etched to form a trench in patterned substrate 400-2. After patterning, patterned silicon oxide layer 410-2 is removed in operation 380.

Conformal carbon layer 420-1 and patterned conformal carbon layer 420-2 may have the same chemical compositions according to embodiments. Similarly, photoresist layer 440-1 and patterned photoresist layer 440-2 may have the same chemical compositions in embodiments. The structure and composition of patterned photoresist layer 440-2 may be responsible for allowing etchants to diffuse through layer 440-2. Patterned conformal carbon layer 420-2 may be denser than patterned photoresist layer 440-2, in embodiments, to prevent the diffusion of etchants all the way to the patterned silicon oxide 410-2/patterned conformal carbon layer 420-2 interface. Patterned conformal carbon layer 420-2 (or conformal carbon layer 420-1) may be 10% more dense, 20% more dense or 30% more dense than patterned photoresist layer 440-2 (or photoresist layer 440-1), according to embodiments. The conformal carbon layer may be deposited using hot-wire CVD or PECVD etc. from a variety of hydrocarbon precursors but higher temperatures were found to correlate with greater reduction in diffusion due presumably to a greater density. Patterned conformal carbon layer 420-2 and conformal carbon layer 420-1 may be hydrophobic in embodiments.

Prevention of diffusion may also be due to the difference in atomic constitution between conformal carbon layer 420-1 and photoresist layer 440-1. Photoresist layer 440-1 may comprise or consist of carbon, hydrogen and oxygen. Dopants may be present in small concentration to adjust the absorption of various wavelengths of light. Conformal carbon layer 420-1 may comprise or consist of carbon and hydrogen in embodiments. Conformal carbon layer 420-1 may comprise or consist of carbon according to embodiments. Conformal carbon layer 420-1 may comprise or consist of carbon, hydrogen and nitrogen in embodiments. Conformal carbon layer 420-1 may be oxygen-free according to embodiments. Despite the differences in composition and/or density, patterned photoresist layer 440-2 and patterned conformal carbon layer 420-2 may be removed during a single operation, in embodiments. The single operation may involve, in part, an oxygen exposure (e.g. in an ashing operation).

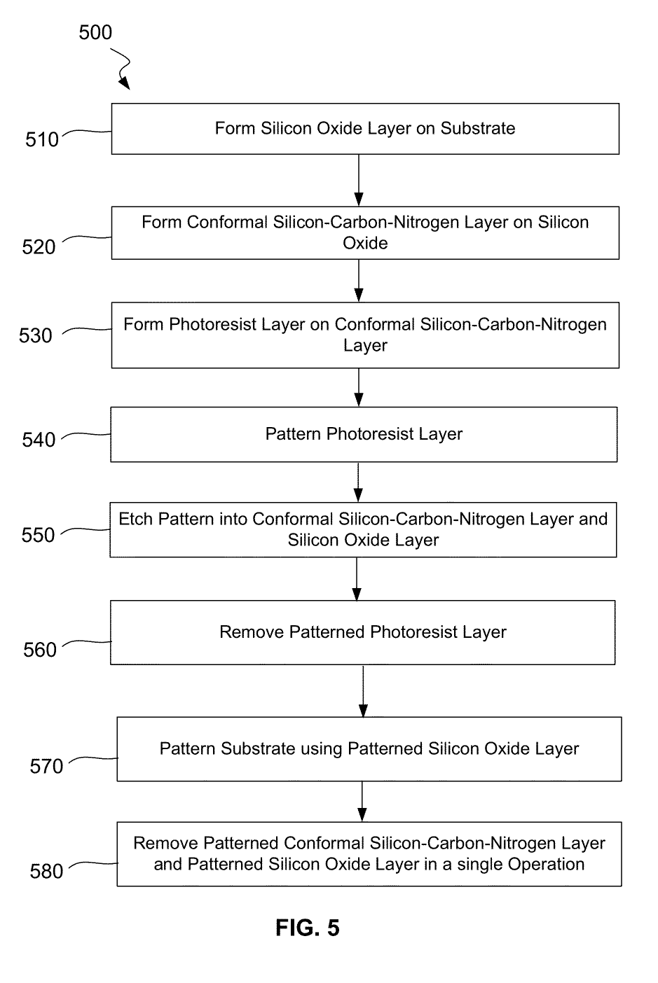

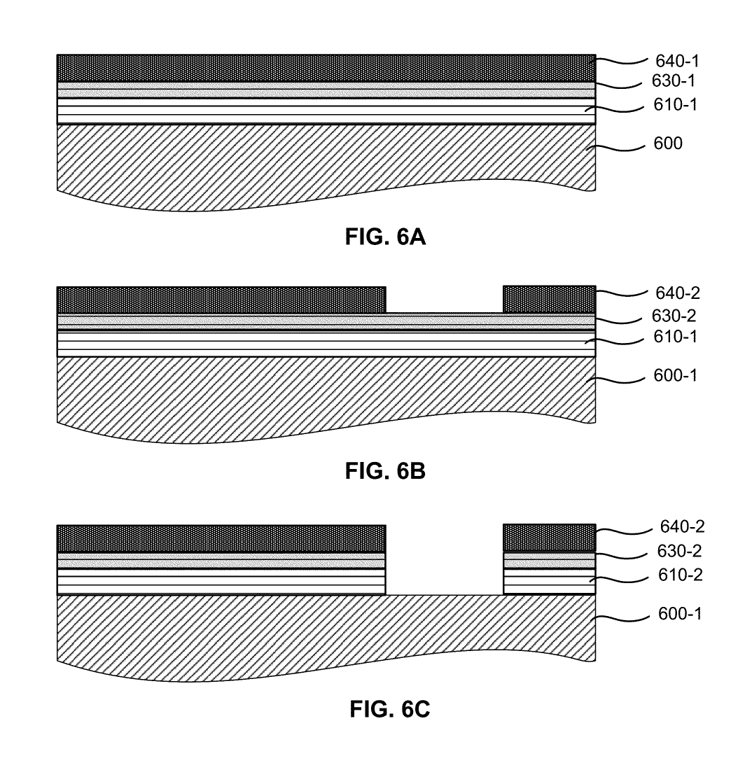

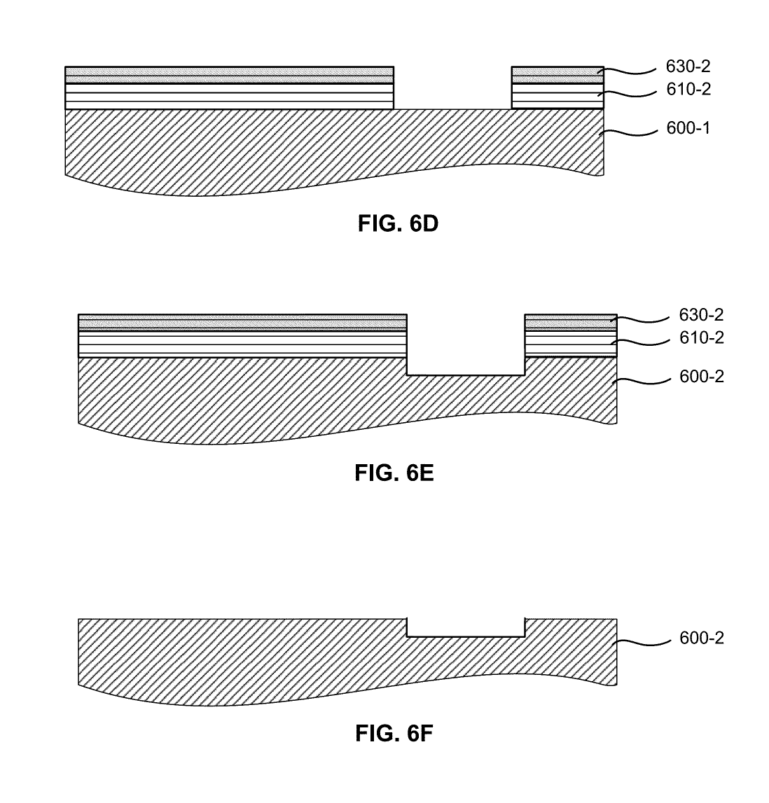

In order to further understand and appreciate the invention, reference is now made to FIG. 5 which shows a method of patterning a substrate 600-1 according to embodiments of the invention. Reference will concurrently be made to FIGS. 6A-6F which are cross-sectional views at various points during the method of FIG. 5. A silicon oxide layer 610-1 is formed on a substrate 600-1 in operation 510. A conformal silicon-containing layer 630-1 is formed on silicon oxide layer 610-1 in operation 520. A photoresist layer 640-1 is then formed on conformal silicon-containing layer 630-1 in operation 530. Photoresist layer 640-1 is patterned in operation 540. Following patterning in operation 540, photoresist layer 640-1 is transformed into patterned photoresist layer 640-2.

Patterned photoresist layer 640-2 is used as a mask to etch the pattern into conformal silicon-containing layer 630-1 to form patterned conformal silicon-containing layer 630-2 (operation 550). Patterned photoresist layer 640-2 is also used as a mask to etch the pattern into silicon oxide layer 610-1 to form patterned silicon oxide layer 610-2 (also operation 550). Alternatively, conformal silicon-containing layer 630-1 and silicon oxide layer 610-1 may be patterned in separate steps depending on whether etchants are available which etch both types of films. Patterned conformal silicon-containing layer 630-2 of various forms described shortly have shown ability to stop diffusion of delicate etch process etchants and protect the integrity of patterned silicon oxide layer 610-2 in embodiments. Patterned photoresist layer 640-2 may remain attached to the stack of materials rather than peeling off as a consequence of the inclusion of patterned conformal silicon-containing layer 630-2.

Patterned photoresist layer 640-2 is removed in operation 560. Operation 560 may involve exposing the patterned substrate to an oxygen atmosphere to remove patterned photoresist layer 640-2. The oxygen exposure may also modify patterned conformal silicon-containing layer 630-2 such that the material is similar to silicon oxide. Following operation 560, the modified film may be referred to herein as “patterned silicon oxide capping layer.” Conformal silicon-containing layer 630-2 may be silicon oxide, in embodiments, following operation 560. The substrate is patterned (operation 570) using patterned silicon oxide layer 610-2 and patterned conformal silicon-containing layer 630-2 as a mask. The patterning may again be an etch process, as shown, or an ion implantation process. In the example, substrate 600-1 is etched to form a trench in patterned substrate 600-2. After patterning, patterned conformal silicon-containing layer 630-2 and patterned silicon oxide layer 610-2 are removed in operation 580. Patterned conformal silicon-containing layer 630-2 may be removed in a single operation along with patterned silicon oxide layer 610-2 because the prior oxygen exposure (operation 560) transformed the material to be stoichiometrically more similar to silicon oxide.

Conformal silicon-containing layer 630-1 and patterned conformal silicon-containing layer 630-2 may have the same chemical compositions according to embodiments. Conformal silicon-containing layer 630-1 may comprise or consist of silicon, carbon and hydrogen in embodiments. Conformal silicon-containing layer 630-1 may comprise or consist of silicon, oxygen, carbon and hydrogen according to embodiments. Conformal silicon-containing layer 630-1 may comprise or consist of silicon, carbon, nitrogen and hydrogen in embodiments. Conformal silicon-containing layer 630-1 may comprise or consist of silicon, oxygen, carbon, nitrogen and hydrogen according to embodiments. The atomic concentration of carbon may be greater than 3%, greater than 5% or greater than 8% of conformal silicon-containing layer 630-2 in embodiments. The atomic concentration of carbon and nitrogen, collectively, may be greater than 3%, greater than 5% or greater than 8% of conformal silicon-containing layer 630-2 in embodiments. Following removal of patterned photoresist layer 640-2 in operation 560, the atomic concentration of carbon and nitrogen, collectively, may be less than 3% of patterned conformal silicon-containing layer 630-2 according to embodiments.

Prior to removal of patterned photoresist layer 640-2 in operation 560, the thickness of the conformal silicon-containing layer may be between about 1 nm and about 25 nm or between about 2 nm and about 15 nm according to embodiments. The thickness of the conformal silicon-containing layer may be less than the thickness of the conformal carbon layer of the earlier example in embodiments. The conformal silicon-containing layer may deposited at lower temperature compared to the conformal carbon layer while providing similar protection against etchant diffusion.

Generally speaking, the conformal carbon-containing films described herein may be silicon-free, oxygen-free and/or nitrogen-free according to embodiments. The conformal carbon-containing films may comprise or consist of carbon and hydrogen in embodiments. The carbon-containing films may comprise or consist of carbon according to embodiments. The carbon-containing films may be amorphous, in embodiments, and may be used as a masking material during the production of patterned substrates.

The conformal carbon-containing layer may comprise carbon, comprise carbon and hydrogen or comprise carbon, hydrogen and nitrogen. The balance of the carbon-containing film may have an atomic concentration less than 0.5%, less than 0.1% or less than 0.01% of any element other than carbon, other than carbon and hydrogen, or other than carbon, hydrogen and nitrogen according to embodiments. The conformal carbon-containing material may be formed from carbon-containing material which further comprises one of sulfur, boron or phosphorus. The conformal carbon-containing layer may consist of carbon or consist of carbon and hydrogen. The thickness of the conformal carbon-containing layer may be between about 2 nm and about 25 nm or between about 3 nm and about 15 nm according to embodiments.

In all cases herein, a “photoresist layer” may be a single layer or may include common additional layers. Exemplary additional layers include antireflective coatings such as bottom antireflective coatings (BARC) or top antireflective coatings (TARC). The substrate on which the silicon oxide layer is deposited in operations 310 and 510 may be patterned before the deposition occurs. The substrate before deposition may comprise a trench having a width less than 15 nm, less than 12 nm or less than 10 nm according to embodiments.

The process sequences described herein may prevent delicate gas-phase etching precursors from diffusing through photoresist layers and damaging underlying layers. Aspects of exemplary etch processes will now be described. A remote plasma region is used to excite a fluorine-containing precursor, such as nitrogen trifluoride. The remote plasma region may be outside or inside the substrate processing chamber, in embodiments, but is at least separated from the substrate processing region by a showerhead. In embodiments, an oxygen-containing precursor (e.g. water, or an alcohol) may be concurrently flowed into the substrate processing region. The presence of water or —OH groups may also discourage penetration of etchants through the an optionally hydrophobic conformal carbon layer. Plasma effluents may be formed from the fluorine-containing precursor and passed through the showerhead and into the substrate processing region. The oxygen-containing precursor may be directly flowed into the substrate processing region and not excited in any plasma prior to entering the substrate processing region. The oxygen-containing precursor may be combined with the plasma effluents in the substrate processing region and the plasma effluents provide the only excitation of the oxygen-containing precursor in embodiments. The patterned substrate temperature is maintained at between −10° C. and about 50° C. or between about 5° C. and about 25° C. during the gas-phase etching process. The pressure in the remote plasma region and/or the substrate processing region during all etch processes may be between about 0.01 Torr and about 30 Torr or between about 1 Torr and about 5 Torr in embodiments. The remote plasma region is disposed remote from the substrate processing region. The remote plasma region is fluidly coupled to the substrate processing region and both regions may be at roughly the same pressure during processing.

The gas-phase etching includes applying power to the fluorine-containing precursor in the remote plasma region to generate the plasma effluents. As would be appreciated by one of ordinary skill in the art, the plasma may include a number of charged and neutral species including radicals and ions. The plasma may be generated using known techniques (e.g., RF, capacitively coupled, inductively coupled). In embodiments, the remote plasma power is applied to the remote plasma region at a level between 5 W and 5 kW or between 25 W and 500 W. The remote plasma power may be applied using inductive coils, in embodiments, in which case the remote plasma will be referred to as an inductively-coupled plasma (ICP). The remote plasma power may be a capacitively-coupled plasma in embodiments.

In embodiments, an ion suppressor (which may be the showerhead) may be used to provide radical and/or neutral species for gas-phase etching. The ion suppressor may also be referred to as an ion suppression element. In embodiments, for example, the ion suppressor is used to filter etching plasma effluents (including radical-fluorine) en route from the remote plasma region to the substrate processing region. The ion suppressor may be used to provide a reactive gas having a higher concentration of radicals than ions. Plasma effluents pass through the ion suppressor disposed between the remote plasma region and the substrate processing region. The ion suppressor functions to dramatically reduce or substantially eliminate ionically charged species traveling from the plasma generation region to the substrate. The electron temperature may be measured using a Langmuir probe in the substrate processing region during excitation of a plasma in the remote plasma region on the other side of the ion suppressor. In embodiments, the electron temperature may be less than 0.5 eV, less than 0.45 eV, less than 0.4 eV, or less than 0.35 eV. These extremely low values for the electron temperature are enabled by the presence of the showerhead and/or the ion suppressor positioned between the substrate processing region and the remote plasma region. Uncharged neutral and radical species may pass through the openings in the ion suppressor to react at the substrate. Such a process using radicals and other neutral species can reduce plasma damage compared to conventional plasma etch processes that include sputtering and bombardment. The ion suppressor helps control the concentration of ionic species in the reaction region at a level that assists the process. Embodiments of the present invention are also advantageous over conventional wet etch processes where surface tension of liquids can cause bending and peeling of small features.

Alternatively, the substrate processing region may be described herein as “plasma-free” during the etch processes described herein. “Plasma-free” does not necessarily mean the region is devoid of plasma. Ionized species and free electrons created within the plasma region may travel through pores (apertures) in the partition (showerhead) at exceedingly small concentrations. The borders of the plasma in the chamber plasma region are hard to define and may encroach upon the substrate processing region through the apertures in the showerhead. Furthermore, a low intensity plasma may be created in the substrate processing region without eliminating desirable features of the etch processes described herein. All causes for a plasma having much lower intensity ion density than the chamber plasma region during the creation of the excited plasma effluents do not deviate from the scope of “plasma-free” as used herein.

As used herein “substrate” may be a support substrate with or without layers formed thereon. A patterned substrate may be an insulator or a semiconductor of a variety of doping concentrations and profiles and may, for example, be a semiconductor substrate of the type used in the manufacture of integrated circuits. Exposed “silicon” of the patterned substrate is predominantly Si but may include minority concentrations of other elemental constituents such as nitrogen, oxygen, hydrogen and carbon. In embodiments, silicon consists of or essentially of silicon. Exposed “silicon oxide” of the patterned substrate is predominantly SiO₂ but may include minority concentrations of other elemental constituents such as nitrogen, hydrogen and carbon. In embodiments, silicon oxide consists of or essentially of silicon and oxygen.

The term “precursor” is used to refer to any process gas which takes part in a reaction to either remove material from or deposit material onto a surface. “Plasma effluents” describe gas exiting from the remote plasma region (e.g. the chamber plasma region) and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” is a radical precursor which contain fluorine but may contain other elemental constituents. The phrase “inert gas” refers to any gas which does not form chemical bonds in the film during or after the etch process. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a trench” includes a plurality of such trenches, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of patterning a substrate, the method comprising:
forming a silicon oxide layer on the substrate;
forming a conformal carbon layer on the silicon oxide;
forming a photoresist layer on the conformal carbon layer;
patterning the photoresist layer with a pattern to form a patterned photoresist layer, wherein the operation of patterning the photoresist layer also patterns the conformal carbon layer with the pattern to form a patterned conformal carbon layer;
etching the pattern into the silicon oxide layer using both the patterned photoresist layer and the patterned conformal carbon layer as the mask, wherein etching the pattern into the silicon oxide layer comprises forming a patterned silicon oxide layer from the silicon oxide layer;
removing the patterned photoresist layer and the patterned carbon layer in a single operation;
patterning the substrate using the patterned silicon oxide layer; and
removing the patterned silicon oxide layer.

2. The method of claim 1 wherein the conformal carbon layer comprises carbon and hydrogen.

3. The method of claim 1 wherein a density of the conformal carbon layer is more than 10% larger than a density of the photoresist layer.

4. The method of claim 1 wherein the conformal carbon layer comprises carbon, hydrogen and nitrogen.

5. The method of claim 1 wherein the conformal carbon layer consists of carbon, hydrogen and nitrogen.

6. The method of claim 1 wherein the conformal carbon layer is oxygen-free.

7. The method of claim 1 wherein the conformal carbon layer is hydrophobic before or after after patterning the photoresist layer.

8. The method of claim 1 wherein the operation of etching the pattern into the silicon oxide layer comprises exciting a fluorine-containing precursor in a remote plasma region to produce plasma effluents which are passed through a showerhead into a substrate processing region housing the substrate.

9. The method of claim 1 wherein a thickness of the conformal carbon-containing layer is between about 2 nm and about 25 nm

10. A method of patterning a substrate, the method comprising:
forming a silicon oxide layer on the substrate;
forming a conformal silicon-containing layer on the silicon oxide, wherein the conformal silicon-containing layer further comprises carbon;
forming a photoresist layer on the conformal silicon-containing layer;
patterning the photoresist layer with a pattern to form a patterned photoresist layer;
etching the pattern into the conformal silicon oxide layer, wherein etching the pattern into the conformal silicon oxide layer comprises forming a patterned silicon oxide layer from the silicon oxide layer, and wherein the operation of etching the pattern into the silicon oxide layer also patterns the conformal silicon-containing layer with the pattern to form a patterned conformal silicon-containing layer;
removing the patterned photoresist layer, wherein removing the patterned photoresist layer also transforms the silicon-containing layer into a patterned silicon oxide capping layer;
patterning the substrate using the patterned silicon oxide capping layer and the patterned silicon oxide layer; and
removing the patterned silicon oxide capping layer and the patterned silicon oxide layer in a single operation.

11. The method of claim 10 wherein the silicon-containing layer further comprises nitrogen.

12. The method of claim 10 wherein the silicon-containing layer comprises silicon, carbon and nitrogen and an atomic concentration of the carbon and nitrogen, collectively, is greater than 3% of the silicon-containing layer.

13. The method of claim 10 wherein the silicon-containing layer further comprises oxygen.

14. The method of claim 10 wherein the silicon-containing layer comprises silicon, oxygen, carbon and hydrogen and an atomic concentration of the carbon is greater than 3% of the silicon-containing layer.

15. The method of claim 10 wherein a thickness of the conformal silicon-containing layer is between about 1 nm and about 25 nm
